(19) United States
(12) Patent Application Publication
(10) Pub. No.: US 2026/0051881 A1
(43) Pub. Date: Feb. 19, 2026

(54) CLOCK PHASE TUNER EMPLOYING SET OF CONFIGURABLE SWITCHED-CURRENT UNIT CELLS

(71) Applicant: QUALCOMM Incorporated, San Diego, CA (US)

(72) Inventors: Yongjian TANG, San Diego, CA (US); Xiaohua KONG, San Diego, CA (US)

(21) Appl. No.: 18/807,335

(22) Filed: Aug. 16, 2024

(51) Int. Cl. H03K 5/01; H03K 5/00

(52) U.S. Cl. CPC H03K 5/01; H03K 2005/00286

(57) ABSTRACT

Clock phase tuning method including supplying a current to a capacitor when first and second clock signals are at a first logic state to generate an voltage across the capacitor during a first interval; supplying or drawing a current to or from the capacitor based on an enable signal when the first and second clock signals are at first and second logic states to generate the voltage across the capacitor during a second interval; drawing a current from the capacitor when the first and second clock signals are at the second logic state to generate the voltage during a third interval; drawing or supplying current from or to the capacitor based on the enable signal when the first and second clock signals are at second and first second logic states to generate the voltage across the capacitor during a fourth interval; and generating a clock signal based on the voltage.

### FIELD

This disclosure relates generally to clock phase tuners, and in particular, to a clock phase tuner including a set of controllable switched-current unit cells cascaded with a transimpedance amplifier (TIA) and output driver (e.g., inverter).

### BACKGROUND

A clock phase tuner is configured to generate a clock signal with a tunable (e.g., adjustable, controllable, shiftable, etc.) phase. A clock signal is a substantially periodic signal which may or may not have a 50 percent duty cycle. Clock phase tuners may be used in many applications such as in clock and data recovery (CDR) for aligning a sampling edge of a sampling clock signal with a center of an eye diagram (e.g., most optimal sampling point) associated with a data signal. Another application for a clock phase turner is in a time-interleaved analog-to-digital converter (ADC), where a clock phase tuner adjusts the phase of one of a pair of sampling clock signals applied to a pair of interleaved ADCs so that their phase difference is substantially 180 degrees.

### SUMMARY

The following presents a simplified summary of one or more implementations in order to provide a basic understanding of such implementations. This summary is not an extensive overview of all contemplated implementations, and is intended to neither identify key or critical elements of all implementations nor delineate the scope of any or all implementations. Its sole purpose is to present some concepts of one or more implementations in a simplified form as a prelude to the more detailed description that is presented later.

An aspect of the disclosure relates to a clock phase tuner. The clock phase tuner includes a capacitor; a set of N switched-current (SI) unit cells collectively configured to: supply a charging current to the capacitor when a first clock signal and a second clock signal are both at a first logic state to generate a voltage across the capacitor during a first time interval; supply a charging current to or draw a discharging current from the capacitor based on an enable signal EN<N-1:0> when the first clock signal is at the first logic state and the second clock signal is at a second logic state to generate the voltage across the capacitor during a second time interval; draw a discharging current from the capacitor when the first clock signal and the second clock signal are both at the second logic state to generate the voltage during a third time interval; and draw a discharging current from and supply a charging current to the capacitor based on the enable signal EN<N-1:0> when the first clock signal is at the second logic state and the second clock signal is at the first logic state to generate the voltage across the capacitor during a fourth time interval; and a clock generator configured to generate an output clock signal based on the voltage.

Another aspect of the disclosure relates to a clock phase tuner. The clock phase tuner includes: a set of N switched-current (SI) unit cells, wherein each of the set of N SI unit cells comprises: a first p-channel field effect transistor (PFET) coupled in series with a first current source between an upper voltage rail and a common output of the set of N SI unit cells, wherein the first PFET includes a gate configured to receive a first clock signal, and wherein the first current source is enabled based on a corresponding bit of an enable signal EN<N-1:0>; a second current source coupled in series with a first n-channel field effect transistor (NFET) between the common output and a lower voltage rail, wherein the first NFET includes a gate configured to receive the first clock signal, and wherein the second current source is enabled based on the corresponding bit of the enable signal EN<N-1:0>; a second PFET coupled in series with a third current source between the upper voltage rail and the common output of the set of N SI unit cells, wherein the second PFET includes a gate configured to receive a second clock signal, and wherein the third current source is enabled based on a corresponding bit of a complementary enable signal EN_b<N-1:0>; and a fourth current source coupled in series with a second NFET between the common output and the lower voltage rail, wherein the second NFET includes a gate configured to receive the second clock signal, wherein the fourth current source is enabled based on the corresponding bit of the complementary enable signal EN_b<N-1:0>; a capacitor coupled between the common output and the lower voltage rail; and a clock generator including an input coupled to the common output, and an output configured to generate a clock signal.

Another aspect of the disclosure relates to a method of generating a clock signal. The method includes supplying a charging current to a capacitor when a first clock signal and a second clock signal are both at a first logic state to generate an voltage across the capacitor during a first time interval; supplying a charging current to or drawing a discharging current from the capacitor based on an enable signal when the first clock signal is at the first logic state and the second clock signal is at a second logic state to generate the voltage across the capacitor during a second time interval; drawing a discharging current from the capacitor when the first clock signal and the second clock signal are both at the second logic state to generate the voltage during a third time interval; drawing a discharging current from or supplying a charging current to the capacitor based on the enable signal when the first clock signal is at the second logic state and the second clock signal is at the first logic state to generate the voltage across the capacitor during a fourth time interval; and generating a clock signal based on the voltage.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the description implementations are intended to include all such aspects and their equivalents.

### BRIEF DESCRIPTION OF THE DRAWINGS

FIG. 1A illustrates a block diagram of an example serializer/deserializer (SERDES) communication link in accordance with an aspect of the disclosure.

FIG. 1B illustrates an eye diagram of an example differential data signal including an associated sampling clock signal in accordance with another aspect of the disclosure.

FIG. 2 illustrates a schematic diagram of an example clock phase tuner in accordance with another aspect of the disclosure.

FIG. 3 illustrates a schematic diagram of another example clock phase tuner in accordance with another aspect of the disclosure.

FIG. 4A illustrates a schematic diagram of another example clock phase tuner in accordance with another aspect of the disclosure.

FIG. 4B illustrates a timing diagram of example signals associated with an operation of the clock phase tuner of FIG. 4A in accordance with another aspect of the disclosure.

FIG. 5 illustrates a flow diagram of another example method of generating a clock signal in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts. The term “substantially” means that the associated parameter may not be exact as indicated but accounts for some variation due to specified tolerances.

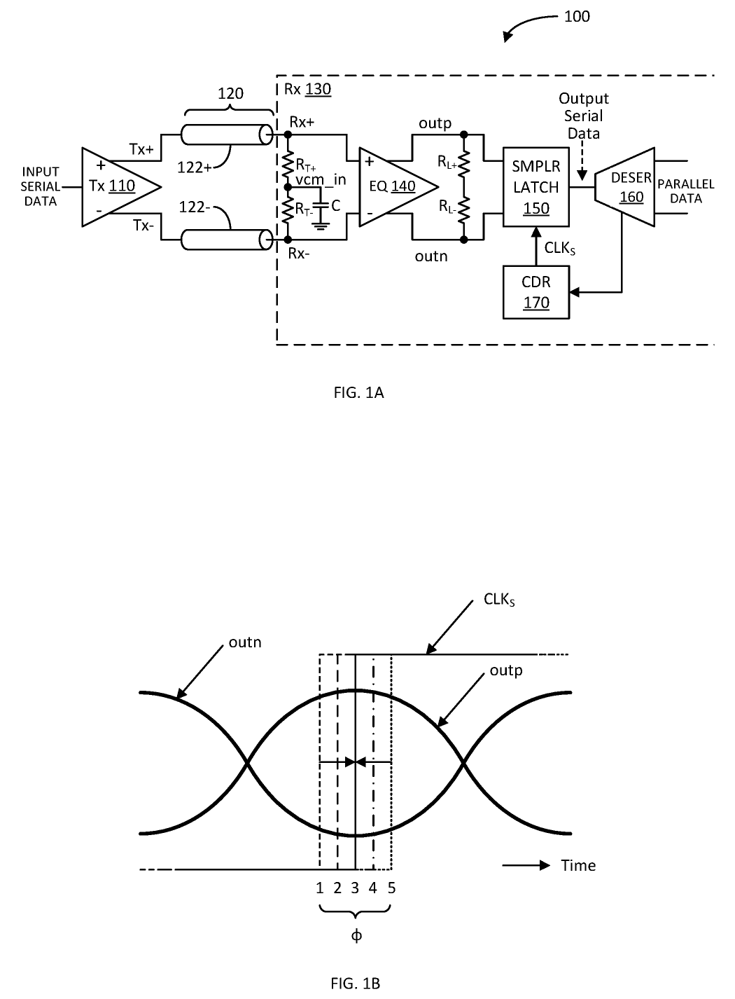

FIG. 1A illustrates a block diagram of an example serializer/deserializer (SERDES) communication link 100 in accordance with an aspect of the disclosure In this example the SERDES communication link 100 includes a single unidirectional data lane However it shall be understood that the SERDES communication link 100 may include a set of one or more unidirectional data lanes and/or a set of one or more bidirectional data lanes.

The SERDES communication link 100 includes a transmitter (Tx) 110 e.g., transmit (Tx) driver) coupled to a receiver 130 via a data communication channel 120. The transmitter 110 may be configured to generate a transmit differential signal Tx+/Tx- based on an input serial data signal. The transmit differential signal Tx+/Tx- may be routed to the receiver 130 via differential transmission lines 122+/122- of the data communication channel 120, respectively. The data communication channel 120 typically has a low-pass frequency response or transfer function that reduces high frequency content of signals that propagate therethrough. Accordingly, at the receiver 130, the transmit differential signal Tx+/Tx- , which may be referred to as a received differential signal Rx+/Rx-, from the perspective of the receiver 130, has its high frequency content reduced due to the data communication channel 120.

The receiver 130, in turn, includes a pair of termination resistors R_{T+} and R_{T-} coupled between the differential transmission lines 122+ and 122- and an input common mode node. An input common mode voltage vcm_in may be generated at the input common mode node based on the received differential signal Rx+/Rx- . The termination resistors R_{T+} and R_{T-} reduce signal reflections at the differential input of the receiver 130. The receiver 130 further includes a capacitor C coupled between the input common mode node and a lower voltage rail (e.g., ground) to filter the input common mode voltage vcm_in.

The receiver 130 includes an equalizer (e.g., a continuous time linear equalizer (CTLE)) 140 including a differential input +/- configured to receive the received differential signal Rx+/Rx-, respectively. The CTLE 140 is configured to equalize or compensate the received differential signal Rx+/Rx- for high frequency losses incurred while propagating via the data communication channel 120 to generate an output differential signal outp/outn across a pair of load resistors R_{L}+/R_{L}-, respectively.

The receiver 130 further includes a sampler/latch 150 configured to sample the output differential signal outp/outn based on a sampling clock signal CLK_{S} to generate an output serial data. Additionally, the receiver 130 includes a deserializer 160 configured to deserialize the output serial data to generate a set of parallel data. Further, the receiver 130 includes a clock and data recovery (CDR) 170 configured to generate the sampling clock signal CLK_{S} based on a feedback signal from the deserializer 160. As discussed in more detail further herein, the CDR 170 may include a clock phase tuner configured to adjust/tune the phase of the sampling clock signal CLK_{S} so that its sampling edge is substantially aligned with the center of an eye associated with the differential data signal outp/outn.

FIG. 1B illustrates an eye diagram of the example differential data signal outp/outn and example sampling clock signal CLK_{S} of the SERDES communication link 100 in accordance with another aspect of the disclosure. The horizontal axis of the eye signal diagram represents time. The vertical axis of the eye signal diagram represents amplitude of the differential data signal outp/outn and sampling clock signal CLK_{S}.

As the eye diagram illustrates, the positive component outp of the differential data signal outp/outn exhibits a positive peak at phase (clock sampling edge) “3” (indicated as a solid line) of the sampling clock signal CLK_{S}. Similarly, the negative component outn of the differential data signal outp/outn exhibits a negative peak at phase “3” of the sampling clock signal CLK_{S}. At phase 3, the amplitude difference between the positive component outp and the negative component outn of the differential data signal outp/outn is maximum (e.g., which coincides with the center of the eye diagram. Accordingly, the phase of the sampling clock signal CLK_{S} being at phase 3 maximizes the successful detection/sampling of the data carried by the differential data signal. Other phases of the sampling clock signal CLK_{S}, such as 1-2 and 4-5 (indicated as various dashed-type lines), are not situated at the maximum amplitude difference between positive component outp and the negative component outn of the differential data signal outp/outn.

Accordingly, if the current phase of the sampling clock signal CLK^{S} is other than at phase 3 (e.g., at phase 1), the amplitude difference between the positive component outp and the negative component outn of the differential data signal outp/outn is not maximum. This information may be fed back to the CDR 170 by the deserializer 160. In response, a clock phase tuner in the CDR 170 adjusts/tunes the phase of the sampling clock signal CLK_{S} so that it is at phase “3” (e.g., shifting the phase from phase 1 to phase 3) until it is determined that the feedback information indicates the maximum difference between the positive component outp and the negative component outn of the differential data signal outp/outn.

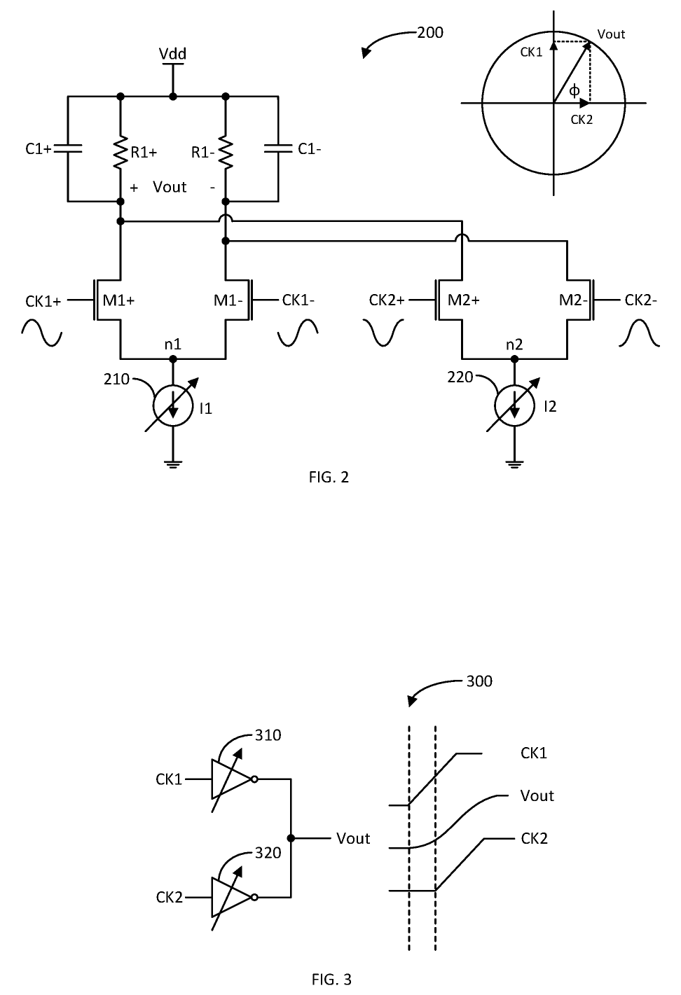

FIG. 2 illustrates a schematic diagram of an example clock phase tuner 200 in accordance with another aspect of the disclosure. The clock phase tuner 200 is implemented as a current-mode logic (CML) based clock phase tuner. A clock phase tuner may also be referred to as a clock phase interpolator or a clock phase shifter.

In particular, the clock phase tuner 200 includes a resistor R1+ coupled in series with a drain and a source of an n-channel field effect transistor (NFET) M1+ between an upper voltage rail Vdd and a node n1. The clock phase tuner 200 further includes a capacitor C1+ coupled in parallel with the resistor R1+. The clock phase tuner 200 further includes a resistor R1- coupled in series with a drain and a source of an NFET M1- between the upper voltage rail Vdd and the node n1. The clock phase tuner 200 further includes a capacitor C1- coupled in parallel with the resistor R1-.

The clock phase tuner 200 also includes a current source 210 coupled between the node n1 and a lower voltage rail (e.g., ground). The current source 210 is configured to generate a substantially constant current I1, which may be programmable. The NFET M1+ includes a gate configured to receive a clock signal CK1+, which may have a substantially sinusoidal waveform. Similarly, the NFET M1- includes a gate configured to receive a clock signal CK1-, which may also have a substantially sinusoidal waveform. The clock signals CK1+ and CK1- cycle with a phase difference of substantially 180 degrees.

The clock phase tuner 200 further includes an NFET M2+ including a drain coupled to the drain of the NFET M1+, a source coupled to a node n2, and a gate configured to receive another clock signal CK2+, which may have a substantially sinusoidal waveform. Additionally, the clock phase tuner 200 includes an NFET M2- including a drain coupled to the drain of NFET M1-, a source coupled to the node n2, and a gate configured to receive a clock signal CK2-, which may have a substantially sinusoidal waveform. The clock phase tuner 200 also includes a current source 220 coupled between the node n2 and the lower voltage rail. The current source 220 is configured to generate a substantially constant current I2, which may be programmable. The clock signals CK1+ and CK2+ cycle with a phase difference of substantially 90 degrees. The clock signals CK1- and CK2- cycle with a phase difference of substantially 180 degrees.

The clock phase tuner 200 is configured to generate a differential voltage Vout across the drains of the NFETs M1+ and M1- (also across the drains of NFETs M2+ and M2- ). With reference to a phase diagram also included in FIG. 2, the differential voltage Vout may cycle with a first phase component based on the differential phase of the clock signals CK1+/CK1-, which is indicated in the phase diagram as a 90-degree component. The amplitude or intensity of the first phase component is based on the current I1. The differential voltage Vout may cycle with a second phase component based on the differential phase of the clock signals CK2+/CK2- , which is indicated in the phase diagram as a 0-degree component (as the phase difference between the clock signals CK1+/CK1- and CK2+/CK2- is 90 degrees. The amplitude or intensity of the second phase component is based on the current I2. Accordingly, the differential voltage Vout cycles with a phase ϕ being substantially the inverse tangent of I1/I2 (e.g., ϕ=tan⁻¹(I1/I2)), as indicated in the phase diagram. Accordingly, by adjusting the current I1 with respect to the current I2 or vice versa the phase of the differential voltage Vout may be tuned.

There are several drawback with the CML-based clock phase tuner 200 First the clock signals CK1+/CK1- and CK2+CK2- applied to the gates of NFETs M1+M1- and M2+/M2- need to be sinusoidal. However, the clock signals CK1+/CK1- and CK2+/CK2- are derived from a base clock signal, which is square wave. Accordingly, filters are required to convert the square wave base clock signal into the sinusoidal clock signals CK1+/CK1- and CK2+/CK2- . The filters may occupy significant integrated circuit (IC) footprint, which is generally undesirable. Further, as indicated above, the phase varies with the inverse tangent of the current intensity ratio I1/I2. This results in a non-linear phase variation for controlling the phase of the output voltage Vout, which may also be undesirable. Moreover, the resistors R1+/R1- may need to have relatively low resistance to produce adequate voltage swing in the output voltage Vout. However, this has the drawback of the CML-based clock phase tuner 200 consuming significant power, which is also generally undesirable. Other drawbacks include the output voltage Vout may not have rail-to-rail voltage swing, the design is complicated, and may not scale well with frequency.

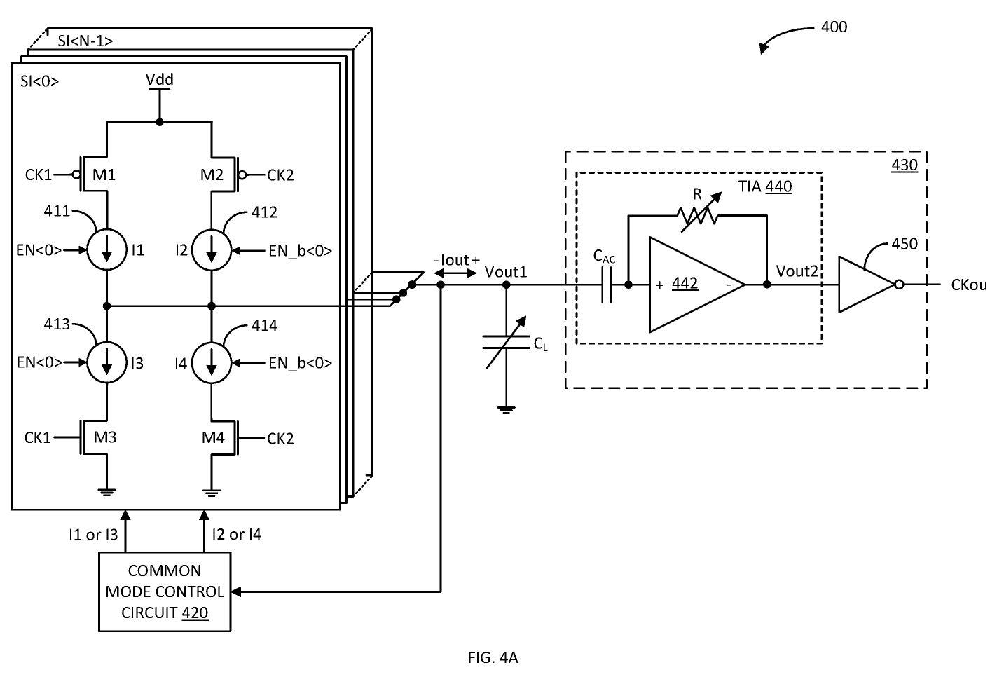

FIG. 3 illustrates a schematic diagram of another example clock phase tuner 300 in accordance with another aspect of the disclosure. The clock phase tuner 300 is implemented as an inverter-based voltage clock phase tuner.

The clock phase tuner 300 includes a first inverter 310 and a second inverter 320. The first inverter 310 includes an input configured to receive a first clock signal CK1. The second inverter 320 includes an input configured to receive a second clock signal CK2. The first and second clock signals CK1 and CK2 cycle with different phases. The first and second inverters 310 and 320 are collectively configured to generate an output voltage Vout at a common output based on the first and second clock signals CK1 and CK2, respectively.

The first and second inverters 310 and 320 may be implemented with a programmable output impedance. That is, each of the first and second inverters 310 and 320 may be implemented with a set of inverters which may be selectively coupled in parallel. The more inverters coupled in parallel, the lower the output impedance, and vice-versa. Accordingly, the phase ϕ of the output voltage Vout may be expressed in accordance with the following equation: ϕ=(ϕ1/ZO1 + ϕ2/ZO2)*(ZO1+ZO2) where ϕ1 is the phase of the first clock signal CK1, ZO1 is the output impedance of the first inverter 310, ϕ2 is the phase of the second clock signal CK2, and ZO2 is the output impedance of the second inverter 320. Accordingly, the phase of the output voltage Vout may be tuned by adjusting the output impedance ZO1 of the first inverter 310 with respect to the output impedance ZO2 of the second inverter 320, or vice-versa.

There are some advantages of the inverter-based voltage clock phase tuner 300 over the CML-based clock phase tuner 200. These may include simpler design, lower power, and output voltage Vout having rail-to-rail voltage swing. On the other hand, the inverter-based voltage clock phase tuner 300 may have worse linearity and higher supply-noise rejection compared to that of the CML-based clock phase tuner 200. Further, as indicated in FIG. 2, the edges of the first and second clock signals CK1 and CK2 need to overlap to produce phase tuning effects in the output voltage Vout. Accordingly, a high slew (edge) rate in the clock signals CK1 and CK2 may result in the edges not overlapping. Thus, the clock signals CK1 and CK2 may need to be slowed down to produce the required overlap of the edges or transitions of the clock signals CK1 and CK2.

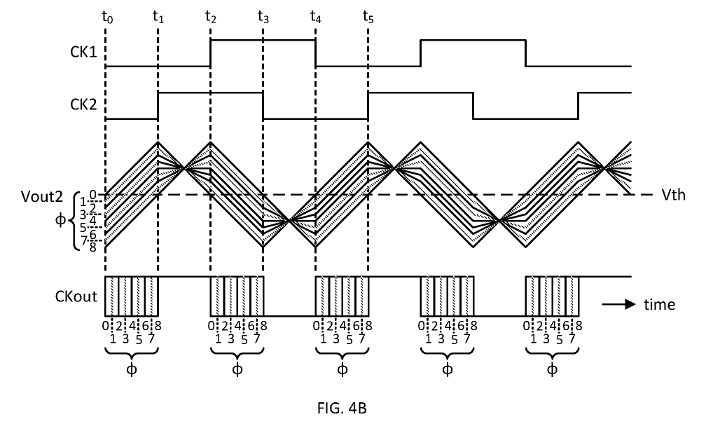

FIG. 4A illustrates a schematic diagram of another example clock phase tuner 400 in accordance with another aspect of the disclosure. As discussed further herein the clock phase tuner 400 may be characterized with improved linearity, low noise, low power, and ease of process and frequency scaling.

The clock phase tuner 400 includes a set of N switched-current (SI) unit cells SI<0> to SI<N-1>, wherein N is an integer (e.g., N=8). Each of the set of N SI unit cells SI<0> to SI<N-1> includes a p-channel field effect transistor (PFET) M1, a current source 411, another current source 413, and an n-channel field effect transistor NFET M3 coupled in series between an upper voltage rail Vdd and a lower voltage rail (e.g., ground). That is, the PFET M1 includes a source coupled to the upper voltage rail Vdd, a gate configured to receive a first clock signal CK1, and a drain. The current source 411 is configured to selectively generate a substantially constant current I1 based on an enable signal EN (e.g., enable signals EN<0> to EN<N-1> for the corresponding current sources 411 of the SI unit cells SI<0> to SI<N-1>, respectively. The current source 411 is coupled between the drain of PFET M1 and a common output of the set of N SI unit cells SI<0> to SI<N-1>.

The current source 413 is configured to selectively generate a substantially constant current I3 based on the enable signal EN (e.g., enable signals EN<0> to EN<N-1> for the corresponding current sources 413 of the SI unit cells SI<0> to SI<N-1> respectively. ). The current source 413 is coupled between the common output of the set of N SI unit cells SI<0> to SI<N-1> and a drain of NFET M3. The NFET M3 includes a gate configured to receive the first clock signal CK1, and a source coupled to the lower voltage rail.

Each of the set of N SI unit cells SI<0> to SI<N-1> includes another PFET M2, a current source 412, another current source 414, and an NFET M4 coupled in series between the upper voltage rail Vdd and the lower voltage rail. That is, the PFET M2 includes a source coupled to the upper voltage rail Vdd, a gate configured to receive a second clock signal CK2, and a drain. The current source 412 is configured to selectively generate a substantially constant current I2 based on a complementary enable signal EN_b (e.g., complementary enable signals EN_b<0> to EN_b<N-1> for the corresponding current sources 412 of the SI unit cells SI<0> to SI<N-1>, respectively. The current source 412 is coupled between the drain of PFET M2 and the common output of the set of N SI unit cells SI<0> to SI<N-1>.

The current source 414 is configured to selectively generate a substantially constant current I4 based on the complementary enable signal EN_b (e.g., complementary enable signals EN_b<0> to EN_b<N-1> for the corresponding current sources 414 of SI unit cells SI<0> to SI<N-1>, respectively. The current source 414 is coupled between the common output of the set of N SI unit cells SI<0> to SI<N-1> and a drain of NFET M4. The NFET M4 includes a gate configured to receive the second clock signal CK2, and a source coupled to the lower voltage rail. The currents I1, I2, I3, and I4 generated by the current sources 411, 412, 413, and 414 may be substantially the same (e.g., I1=I2=I3=I4, which may be referred to generally as I).

The first and second clock signals CK1 and CK2 may each have a substantially square wave waveform. The first and second clock signals CK1 and CK2 may have a specified phase difference Δϕ between each other, such as 90 degrees or other. Accordingly, as discussed in more detail further herein the clock phase tuner 400 may have a phase tuning resolution of ΔϕN. Thus, for the case where the phase difference between the first and second clocks CK1 and CK2 is 90 degrees and the number N of SI unit cells is eight (8), the clock phase tuner 400 may have a phase tuning resolution of 90 degrees/8 or 11.25 degrees.

The clock phase tuner 400 may further include a load capacitor C_{L} coupled between the common output of the set of N SI unit cells SI<0> to SI<N-1> and the lower voltage rail. The load capacitor C_{L} may have a programmable capacitance. As discussed further herein, the set of N SI unit cells SI<0> to SI<N-1> are configured to generate charging and discharging currents based on the first and second clock signals CK1 and CK2 and the complementary enable signals EN and EN_b. The load capacitor C_{L} is configured to integrate the charging and discharging currents to generate a first output voltage Vout1 across the load capacitor C_{L}.

The clock phase tuner 400 may optionally include a common mode control circuit 420 to control a common mode voltage associated with the first output voltage Vout1 to be, for example, at substantially half of the supply voltage at the upper voltage rail Vdd (e.g., Vdd/2 where the supply voltage is also referred to as Vdd). In this regard, the common mode control circuit 420 includes an input coupled to the common output of the set of N SI unit cells SI<0> to SI<N-1> to receive the first output voltage Vout1, and outputs coupled to the charging current sources 411/412 and/or the discharging current sources 413/414. The common mode control circuit 420 is configured to control the currents I1/I2 or I3/I4 generated by the current sources 411/412 or 413/414 based on the first output voltage Vout1, respectively. For example, if the common mode voltage associated with the first output voltage Vout1 is significantly above Vdd/2 where it may impact the headroom voltage for the PFETs M1/M2 and current sources 411/412, the common mode control circuit 420 may control the charging current sources 411/412 to decrease its currents I1/I2 to reduce the common mode voltage of the first output voltage Vout1. The first output voltage Vout1 may not have full rail-to-rail (e.g., Vdd-to-0V) voltage swing.

The clock phase tuner 400 further includes a clock signal generator 430 configured to generate an output clock signal CKout based on the first output voltage Vout1. The clock signal generator 430 includes a transimpedance amplifier (TIA) 440 including an inverter-based amplifier 442, an alternating-current (AC)-coupled capacitor C_{AC}, and a feedback resistor R. The AC-coupled capacitor C_{AC} is coupled between the common output of the set of N SI unit cells SI<0> to SI<N-1> and an input (+) of the inverter-based amplifier 442. The feedback resistor R is coupled between an output (-) and the input (+) of the inverter-based amplifier 442. The feedback resistor R may have a programmable resistance. The TIA 440 is configured to generate a second output voltage Vout2 with a substantially full rail-to-rail swing based on the first output voltage Vout1. Additionally, the clock phase tuner 400 may include an output driver, such as an inverter 450, configured to generate an output clock signal CKout based on the second output voltage Vout2. The operation of the clock phase tuner 400 is discussed further herein with additional reference to a signal timing diagram depicted in FIG. 4B.

FIG. 4B illustrates a timing diagram of example signals associated with an operation of the clock phase tuner 400 in accordance with another aspect of the disclosure. The horizontal axis of the timing diagram represents time. The vertical axis, from top to bottom, represents the logic state of the first clock signal CK1, the logic state of the second clock signal CK2, the amplitude of the second output voltage signal Vout2 associated with a set of N+1 programmable phases (e.g., 0 to 8, where N=8), and the logic state of the output clock signal CLKout associated with the set of N+1 programmable phases. In this example, even phases 0, 2, 4, 6, and 8 are represented with solid black lines, and odd phases 1, 3, 5, and 7 are represented with gray lines.

During time interval t₀ to t₁, the first and second clock signals CK1 and CK2 are both at a logic low state. With regard to each of the set of N SI unit cells SI<0> to SI<N-1>, the corresponding PFETs M1 and M2 are turned on, and the corresponding NFETs M3 and M4 are turned off. The corresponding PFETs M1 and M2 being turned on allow the enabled one of the current source 411 or 412 (based on the state of the complementary enable signals EN and EN_b) to supply a charging current to the load capacitor C_{L}. As the current sources 411 and 412 may be configured to generate substantially the same current I, the magnitude of the charging current Iout provided to the load capacitor C_{L} collectively by the set of N SI unit cells SI<0> to SI<N-1> is substantially the same 8*I independent of the states of the enable signals EN<0>/EN_b<0> to EN<N-1>/EN_b<N-1>, respectively. Accordingly, during time interval t₀ to t₁, the first output voltage Vout1, and by extension, the second output voltage Vout2 increases with substantially the same slope regardless of its current phase (e.g., one of 0 to N=8 phases).

During the next time interval t₁ to t₂, the first and second clock signals CK1 and CK2 are at logic low and high states, respectively. With regard to each of the set of N SI unit cells SI<0> to SI<N-1>, the corresponding PFET M1 and NFET M4 are turned on, and the corresponding PFET M2 and NFET M3 are turned off. Depending on the state of the j^{th} complementary enable signal EN<j>/EN_b<j>, the corresponding SI<j> unit cell is either supplying a charging current to or drawing a discharging current from the load capacitor C_{L}.

For example, if the logic state of the complementary enable signal EN<j>/EN_b<j> is high/low (1/0), the corresponding SI<j> unit cell is supplying a charging current I1 to the load capacitor C_{L} (e.g., because the logic low state of the first clock signal CK1 turns on PFET M1, and the logic high state of the enable signal EN<j> enables the current source 411). If the logic state of the complementary enable signal EN<j>/EN_b<j> is low/high (0/1), the corresponding SI<j> unit cell is drawing a discharging current I4 from the load capacitor C_{L} (e.g., because the logic high state of the second clock signal CK2 turns on NFET M4, and the logic high state of the complementary enable signal EN_b<j> enables current source 414). Accordingly, when the first and second clock signals CK1 and CK2 are at logic low and high states, respectively, an output current Iout provided to or discharged from the load capacitor C_{L} collectively by the set of N SI unit cells SI<0> to SI<N-1> depends on a thermometer code k indicated by EN<7:0>.

In general, for the case where the first and second clock signals CK1 and CK2 are low/high (0/1), the output current Iout provided to or discharged from the load capacitor C_{L} may be expressed as Iout=k*I1-(N-k)*I4, where a positive Iout indicates a charging current and a negative Iout indicates a discharging current. If all the current sources 411, 412, 413, and 414 are configured to each generate the same current I (e.g., I=I1=I2=I3=I4 or substantially 1/N times the maximum or minimum charging or discharging current), the output current Iout may be expressed as Iout=k*I-(N-k)*I.

Considering a few examples: for the case where k=0, the set of N SI unit cells SI<0> to SI<N-1> collectively draw a discharging output current Iout of 0*I-(8-0)*I=-8*I from the load capacitor C_{L}. This produces a maximum negative slope for the second output voltage Vout2 during time interval t₁-t₂, which corresponds to the phase k=0 of the second output voltage Vout2. For the case where k=1, the set of N SI unit cells SI<0> to SI<N-1> collectively draw a discharging output current Iout of 1*I-(8-1)*I=-6*I from the load capacitor C_{L}. This produces the next most negative slope for the second output voltage Vout2 during time interval t₁-t₂, which corresponds to the phase k=1 of the second output voltage Vout2.

For the case where k=4, the set of N SI unit cells SI<0> to SI<N-1> generate substantially no net current (e.g., Iout~0) because half or 4 of the 8 SI unit cells are supplying a charging current 4*I to the load capacitor C_{L}, and the other half or 4 of the 8 SI unit cells are drawing a discharging current -4*I from the load capacitor C_{L} (e.g., Iout=4*I-(8-4)*I=0). This produces a zero (0) slope for the second output voltage Vout2 during time interval t₁-t₂, which corresponds to the phase k=4 of the second output voltage Vout2. For the case where k=5, the set of N SI unit cells SI<0> to SI<N-1> collectively supply a charging output current Iout of 5*I-(8-5)*I=2*I to the load capacitor C_{L}. This produces the least positive slope for the second output voltage Vout2 during time interval t₁-t₂, which corresponds to the phase k=5 of the second output voltage Vout2.

For the case where k=7, the set of N SI unit cells SI<0> to SI<N-1> collectively supply a charging output current Iout of 7*I-(8-7)*I=6*I to the load capacitor C_{L}. This produces the second most positive slope for the second output voltage Vout2 during time interval t₁-t₂, which corresponds to the phase k=7 of the second output voltage Vout2. For the case where k=8, the set of N SI unit cells SI<0> to SI<N-1> collectively supply a charging output current Iout of 8*I-(8-8)*I=8*I to the load capacitor C_{L}. This produces the maximum positive slope for the second output voltage Vout2 during time interval t₁-t₂, which corresponds to the phase k=8 of the second output voltage Vout.

During time interval t₂ to t₃, the first and second clock signals CK1 and CK2 are both at a logic high state. With regard to each of the set of N SI unit cells SI<0> to SI<N-1>, the corresponding PFETs M1 and M2 are turned off, and the corresponding NFETs M3 and M4 are turned on. The corresponding NFETs M3 and M4 being turned on allow the enabled one of the current source 413 or 414 (based on the state of the complementary enable signals EN and EN_b) to draw a discharging current from the load capacitor C_{L}. As the current sources 413 and 414 may be configured to generate substantially the same current I, the magnitude of the discharging current drawn from the load capacitor C_{L} collectively by the set of N SI unit cells SI<0> to SI<N-1> is substantially the same substantially independent of the states of the enable signals EN<0>/EN_b<0> to EN<N-1>/EN_b<N-1>, respectively. Accordingly, during time interval t₂ to t₃, the second output voltage Vout2 decreases with substantially the same slope independent of its current phase (e.g., one of 0 to N=8 phases).

During time interval t₃ to t₄, the first and second clock signals CK1 and CK2 are at logic high and low states, respectively. With regard to each of the set of N SI unit cells SI<0> to SI<N-1>, the corresponding PFET M2 and NFET M3 are turned on, and the corresponding PFET M1 and NFET M4 are turned off. Depending on the state of the j^{th} complementary enable signal EN<j>/EN_b<j>, the corresponding SI<j> unit cell is supplying a charging current to or drawing a discharging current from the load capacitor C_{L}.

For example, if the logic state of the complementary enable signal EN<j>/EN_b<j> is high/low (1/0), the corresponding SI<j> unit cell is drawing a discharging current I3 from the load capacitor C_{L} (e.g., because the logic high state of the first clock signal CK1 turns on NFET M3, and the logic high state of the enable signal EN<j> enables the current source 413). If the logic state of the complementary enable signal EN<j>/EN_b<j> is low/high (0/1), the corresponding SI<j> unit cell is supplying a charging current I2 to the load capacitor C_{L} (e.g., because the logic low state of the second clock signal CK2 turns on PFET M2, and the logic high state of the complementary enable signal EN_b<j> enables current source 412). Accordingly, when the first and second clock signals CK1 CK2 are at logic high and low states, respectively, an output current Iout provided to or discharged from the load capacitor C_{L} collectively by the set of N SI unit cells SI<0> to SI<N-1> depends on the thermometer code k of the enable signal EN<7:0>.

In general, for the case where the first and second clock signals CK1 and CK2 are low/high (0/1), the output current Iout provided to or discharged from the load capacitor C_{L} may be expressed as Iout=(N-k)*I3-k*I2, where a positive Iout indicates a charging current and a negative Iout indicates a discharging current. If all the current sources 411, 412, 413, and 414 are configured to each generate the same current I (e.g., I=I1=I2=I3=I4 or substantially 1/N time the maximum or minimum charging or discharging current), the output current Iout may be expressed as Iout=(N-k)*I-k*I.

Considering a few examples: for the case where k=0, the set of N SI unit cells SI<0> to SI<N-1> collectively supply an output current Iout of (8-0)*I-0*I=8*I to the load capacitor C_{L}. This produces a maximum positive slope for the second output voltage Vout2 during time interval t₃-t₄, which corresponds to the phase k=0 of the second output voltage Vout2. For the case where k=1, the set of N SI unit cells SI<0> to SI<N-1> collectively supply a charging output current Iout of (8-1)*I-1*I=6*I to the load capacitor C_{L}. This produces the next most positive slope for the second output voltage Vout2 during time interval t₃-t₄, which corresponds to the phase k=1 of the second output voltage Vout2.

For the case where k=4, the set of N SI unit cells SI<0> to SI<N-1> generate substantially no net current Iout because half or 4 of the 8 SI unit cells are supplying charging currents to the load capacitor C_{L}, and the other half or 4 of the 8 SI unit cells are drawing a discharging current from the load capacitor C_{L} (e.g., Iout=(8-4)*I-4*I=0). This produces a zero (0) slope for the second output voltage Vout2 during time interval t₃-t₄, which corresponds to the phase k=4 of the second output voltage Vout2. For the case where k=5, the set of N SI unit cells SI<0> to SI<N-1> collectively draw a discharging output current Iout of Iout=(8-5)*I-5*I=-2*I) from the load capacitor C_{L}. This produces the least negative slope for the second output voltage Vout2 during time interval t₃-t₄, which corresponds to the phase k=5 of the second output voltage Vout2.

For the case where k=7, the set of N SI unit cells SI<0> to SI<N-1> collectively draw a discharging output current Iout of (8-7)*I-7*I=-6*I from the load capacitor C_{L}. This produces the second most negative slope for the second output voltage Vout2 during time interval t₃-t₄, which corresponds to the phase k=7 of the second output voltage Vout2. For the case where k=8, the set of N SI unit cells SI<0> to SI<N-1> collectively draw a discharging output current Iout of (8-8)*I-8*I=-8*I from the load capacitor C_{L}. This produces the maximum positive slope for the second output voltage Vout2 during time interval t₃-t₄, which corresponds to the phase k=8 of the second output voltage Vout2.

The timing diagram of FIG. 4B also includes a dashed line representing a threshold voltage Vth of the inverter 450. When the second output voltage Vout2 crosses the threshold voltage Vth from below, the inverter 450 generates a rising edge of output clock signal CKout. When the second output voltage Vout2 crosses the threshold voltage Vth from above, the inverter 450 generates a falling edge of the output clock signal CKout. Accordingly, by controlling the set N SI unit cells SI<0> to SI<N-1> to control the second output voltage Vout2, especially during the intervals when the first and second clock signals CK1 and CK2 are at opposite logic states (e.g., intervals t₁-t₂ and t₃-t₄), the phase of the output clock signal CKout may be tuned. Thus, as indicated in the timing diagram associated with the output clock signal CKout, different phases 0-8 of the output clock signal CKout may be achieved.

The clock phase tuner 400 has several advantages over the clock phase tuners 200 and 300. For example, the clock phase tuner 400 has improved linearity over clock phase tuners 200 and 300 because phase tuning is effectuated by reconfiguring one or more of the set of N SI unit cells SI<0> to SI<N-1> from supplying the same current to drawing the same current, where the load capacitor C_{L} has a substantially constant. Thus, the same step size current change plus the constant capacitance produce linear slopes of the first output voltage Vout2 (and by extension, the second output voltage Vout2); resulting in a substantially linear tuning of the phase of the output clock signal CKout.

The feedback resistor R and AC-coupled capacitor C_{AC} of the TIA 440 may be set to low values to configure the TIA 440 to have a high pass filter (HPF) frequency response with a relatively high pass cutoff frequency. This improves the bandwidth of the clock phase tuner, as well as suppresses low frequency noise from ending up at the output clock signal CKout. The current sources 411, 412, 413, and 414 of the set of N SI unit cells SI<0> to SI<N-1> may be configured to generate the smallest currents while producing sufficient voltage swing in the first output voltage Vout1. Thus, the clock phase tuner 400 may be configured to consume relatively small amount of power. Additionally, amplifier 432 of the TIA 440, being inverter-based, also draws relatively small power.

Further, the clock phase tuner 400 facilitates frequency scaling. For example, the currents I1-I4 generated by the current sources 411, 412, 413, and 414 may change proportionally with frequency of the clock signals CK1 and CK2 (e.g., frequency is reduced by half, currents I1-I4 are reduced by half, and vice-versa). If the currents I1-I4 cannot be reduced proportionally with the frequency (e.g., due to being bottomed out), the capacitance of the load capacitor C_{L} may then be increased proportionally with further decrease in frequency of the clock signals CK1 and CK2.

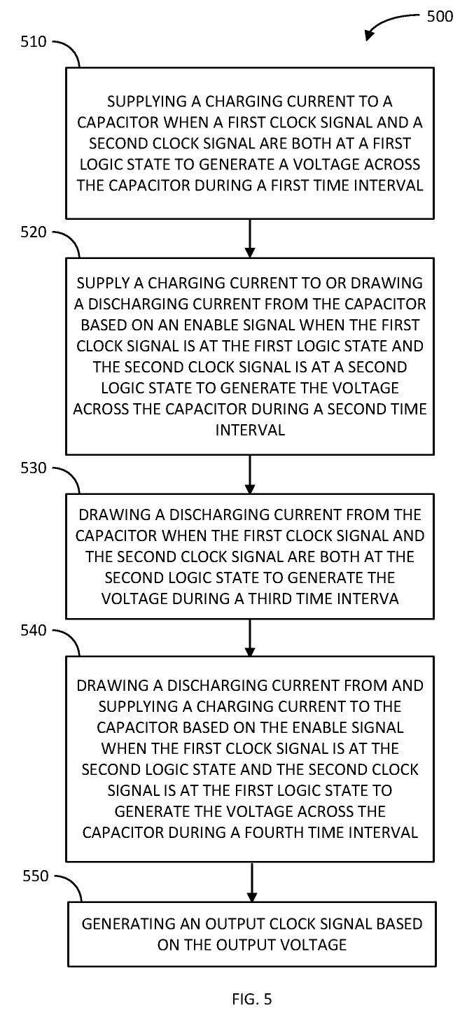

FIG. 5 illustrates a flow diagram of another example method 500 of generating a clock signal in accordance with another aspect of the disclosure. The method 500 includes supplying a charging current to the capacitor when a first clock signal and a second clock signal are both at a first logic state to generate a voltage across the capacitor during a first time interval (block 510). An examples of a means for supplying a charging current to the capacitor when a first clock signal and a second clock signal are both at a first logic state to generate a voltage across the capacitor during a first time interval includes the set of N SI unit cells SI<0> to SI<N-1>.

The method 500 further includes supplying a charging current to or drawing a discharging current from the capacitor based on an enable signal when the first clock signal is at the first logic state and the second clock signal is at a second logic state to generate the voltage across the capacitor during a second time interval (block 520). An example of means for supplying a charging current to or drawing a discharging current from the capacitor based on an enable signal when the first clock signal is at the first logic state and the second clock signal is at a second logic state to generate the voltage across the capacitor during a second time interval includes the set of N SI unit cells SI<0> to SI<N-1>.

Additionally, the method 500 includes drawing a discharging current from the capacitor when the first clock signal and the second clock signal are both at the second logic state to generate the voltage during a third time interval (block 530). An example of means for drawing a discharging current from the capacitor when the first clock signal and the second clock signal are both at the second logic state to generate the voltage during a third time interval includes the set of N SI unit cells SI<0> to SI<N-1>.

Further, the method 500 includes drawing a discharging current from or supplying a charging current to the capacitor based on the enable signal when the first clock signal is at the second logic state and the second clock signal is at the first logic state to generate the voltage across the capacitor during a fourth time interval (block 540). An example of means for drawing a discharging current from or supplying a charging current to the capacitor based on the enable signal when the first clock signal is at the second logic state and the second clock signal is at the first logic state to generate the voltage across the capacitor during a fourth time interval includes the set of N SI unit cells SI<0> to SI<N-1>.

The method 500 additionally includes generating a clock signal based on the voltage (block 550). Examples of means for generating a clock signal based on the voltage include any of the TIA and/or the output driver (e.g., inverter) 440.

The following provides an overview of aspects of the present disclosure:

Aspect 1: A clock phase tuner, comprising: a capacitor; a set of N switched-current (SI) unit cells collectively configured to: supply a charging current to the capacitor when a first clock signal and a second clock signal are both at a first logic state to generate a voltage across the capacitor during a first time interval; supply a charging current to or draw a discharging current from the capacitor based on an enable signal EN<N-1:0> when the first clock signal is at the first logic state and the second clock signal is at a second logic state to generate the voltage across the capacitor during a second time interval; draw a discharging current from the capacitor when the first clock signal and the second clock signal are both at the second logic state to generate the voltage during a third time interval; and draw a discharging current from and supply a charging current to the capacitor based on the enable signal EN<N-1:0> when the first clock signal is at the second logic state and the second clock signal is at the first logic state to generate the voltage across the capacitor during a fourth time interval; and a clock generator configured to generate an output clock signal based on the voltage.

Aspect 2: The clock phase tuner of aspect 1, wherein the set of N SI unit cells are collectively configured to supply the charging current to the capacitor during the first time interval with a magnitude substantially independent of a value of the enable signal EN<N-1:0>.

Aspect 3: The clock phase tuner of aspect 1 or 2, wherein the set of N SI unit cells are collectively configured to supply the charging current to or draw the discharging current from the capacitor during the second time interval based on a thermometer code k indicated by the enable signal EN<N-1:0>.

Aspect 4: The clock phase tuner of any one of aspects 1-3, wherein the set of N SI unit cells are collectively configured to supply the charging current to or draw the discharging current from the capacitor during the second time interval in accordance with k*I-(N-k)*I, wherein I represents substantially a same magnitude of a current generated by each of the set of N SI unit cells, and wherein a positive value of k*I-(N-k)*I indicates the charging current and a negative value of k*I-(N-k)*I indicates the discharging current.

Aspect 5: The clock phase tuner of any one of aspects 1-4, wherein the set of N SI unit cells are collectively configured to draw the discharging current from the capacitor during the third time interval with a magnitude substantially independent of a value of the enable signal EN<N-1:0>.

Aspect 6: The clock phase tuner of any one of aspects 1-5, wherein the set of N SI unit cells are collectively configured to draw the discharging current from or supply the charging current to the capacitor during the fourth time interval based on a thermometer code k indicated by the enable signal EN<N-1:0>.

Aspect 7: The clock phase tuner of aspect 6, wherein the set of N SI unit cells are collectively configured to draw the discharging current from or supply the charging current to the capacitor during the fourth time interval in accordance with (N-k)*I-k*I, wherein I represents substantially a same magnitude of a current generated by each of the set of N SI unit cells, and wherein a negative value of (N-k)*I-k*I indicates the discharging current and a positive value of k*I-(N-k)*I indicates the charging current.

Aspect 8: The clock phase tuner of any one of aspects 1-7, wherein the set of N SI unit cells are collectively configured to produce substantially no net current to or from the capacitor based on a value of the enable signal EN<N-1:0> during the second time interval.

Aspect 9: The clock phase tuner of any one of aspects 1-8, wherein the set of N SI unit cells are collectively configured to produce substantially no net current to or from the capacitor based on a value of the enable signal EN<N-1:0> during the fourth time interval.

Aspect 10: The clock phase tuner of any one of aspects 1-9, wherein the clock generator comprises a transimpedance amplifier (TIA).

Aspect 11: The clock phase tuner of aspect 10, wherein the TIA comprises: an inverter-based amplifier; an alternating-current (AC)-coupled capacitor coupled between a common output of the set of N SI unit cells and an input of the inverter-based amplifier; and a feedback resistor coupled between an output and the input of the inverter-based amplifier.

Aspect 12: The clock phase tuner of aspect 10 or 11, further comprising a driver including an input coupled to an output of the TIA, wherein the driver is configured to generate the output clock signal.

Aspect 13: A clock phase tuner, comprising: a set of N switched-current (SI) unit cells, wherein each of the set of N SI unit cells comprises: a first p-channel field effect transistor (PFET) coupled in series with a first current source between an upper voltage rail and a common output of the set of N SI unit cells, wherein the first PFET includes a gate configured to receive a first clock signal, and wherein the first current source is enabled based on a corresponding bit of an enable signal EN<N-1:0>; a second current source coupled in series with a first n-channel field effect transistor (NFET) between the common output and a lower voltage rail, wherein the first NFET includes a gate configured to receive the first clock signal, and wherein the second current source is enabled based on the corresponding bit of the enable signal EN<N-1:0>; a second PFET coupled in series with a third current source between the upper voltage rail and the common output of the set of N SI unit cells, wherein the second PFET includes a gate configured to receive a second clock signal, and wherein the third current source is enabled based on a corresponding bit of a complementary enable signal EN_b<N-1:0>; and a fourth current source coupled in series with a second NFET between the common output and the lower voltage rail, wherein the second NFET includes a gate configured to receive the second clock signal, wherein the fourth current source is enabled based on the corresponding bit of the complementary enable signal EN_b<N-1:0>; a capacitor coupled between the common output and the lower voltage rail; and a clock generator including an input coupled to the common output, and an output configured to generate a clock signal.

Aspect 14: The clock phase tuner of aspect 13, further comprising a control circuit configured to adjust the first and third current sources and/or the second and fourth current sources to control a common mode voltage associated with the voltage.

Aspect 15: A method of generating a clock signal, comprising: supplying a charging current to a capacitor when a first clock signal and a second clock signal are both at a first logic state to generate a voltage across the capacitor during a first time interval; supplying a charging current to or drawing a discharging current from the capacitor based on an enable signal when the first clock signal is at the first logic state and the second clock signal is at a second logic state to generate the voltage across the capacitor during a second time interval; drawing a discharging current from the capacitor when the first clock signal and the second clock signal are both at the second logic state to generate the voltage during a third time interval; drawing a discharging current from or supplying a charging current to the capacitor based on the enable signal when the first clock signal is at the second logic state and the second clock signal is at the first logic state to generate the voltage across the capacitor during a fourth time interval; and generating a clock signal based on the voltage.

Aspect 16: The method of aspect 15, wherein supplying the charging current during the first time interval comprises supplying the charging current with a magnitude substantially independent of the enable signal.

Aspect 17: The method of aspect 15 or 16, wherein supplying the charging current to or drawing the discharging current from the capacitor during the second time interval comprises supplying the charging current or drawing the discharging current in accordance with k*I-(N-k)*I, wherein k is a thermometer code indicated by the enable signal and N is an integer, wherein I is substantially 1/N times a magnitude of the discharging current or the charging current, and wherein a positive value of k*I-(N-k)*I indicates the charging current and a negative value of k*I-(N-k)*I indicates the discharging current.

Aspect 18: The method of any one of aspects 15-17, wherein drawing the discharging current from the capacitor during the third time interval comprises drawing the discharging current with a magnitude substantially independent of a value of the enable signal.

Aspect 19: The method of any one of aspects 15-18, wherein drawing the discharging current from or supplying the charging current to the capacitor during the fourth time interval comprises drawing the discharging current or supplying the charging current in accordance with (N-k)*I-k*I, wherein k is a thermometer code indicated by the enable signal and N is an integer, wherein I is substantially 1/N times a magnitude of a maximum discharging current or a maximum charging current, and wherein a negative value of (N-k)*I-k*I indicates the discharging current and a positive value of (N-k)*I-k*I indicates the charging current.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

Aspect 20: The method of any one of aspects 15-19, further comprising producing substantially no net current to or from the capacitor based on a value of the enable signal during the second time interval or the fourth time interval.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

WHAT IS CLAIMED:

1. A clock phase tuner, comprising:
a capacitor;
a set of N switched-current (SI) unit cells collectively configured to:
supply a charging current to the capacitor when a first clock signal and a second clock signal are both at a first logic state to generate a voltage across the capacitor during a first time interval;
supply a charging current to or draw a discharging current from the capacitor based on an enable signal EN<N-1:0> when the first clock signal is at the first logic state and the second clock signal is at a second logic state to generate the voltage across the capacitor during a second time interval;
draw a discharging current from the capacitor when the first clock signal and the second clock signal are both at the second logic state to generate the voltage during a third time interval; and
draw a discharging current from or supply a charging current to the capacitor based on the enable signal EN<N-1:0> when the first clock signal is at the second logic state and the second clock signal is at the first logic state to generate the voltage across the capacitor during a fourth time interval; and
a clock generator configured to generate an output clock signal based on the voltage.

2. The clock phase tuner of claim 1, wherein the set of N SI unit cells are collectively configured to supply the charging current to the capacitor during the first time interval with a magnitude substantially independent of a value of the enable signal EN<N-1:0>.

3. The clock phase tuner of claim 1, wherein the set of N SI unit cells are collectively configured to supply the charging current to or draw the discharging current from the capacitor during the second time interval based on a thermometer code k indicated by the enable signal EN<N-1:0>.

4. The clock phase tuner of claim 3, wherein the set of N SI unit cells are collectively configured to supply the charging current to or draw the discharging current from the capacitor during the second time interval in accordance with k*I-(N-k)*I, wherein I represents substantially a same magnitude of a current generated by each of the set of N SI unit cells, and wherein a positive value of k*I-(N-k)*I indicates the charging current and a negative value of k*I-(N-k)*I indicates the discharging current.

5. The clock phase tuner of claim 1, wherein the set of N SI unit cells are collectively configured to draw the discharging current from the capacitor during the third time interval with a magnitude substantially independent of a value of the enable signal EN<N-1:0>.

6. The clock phase tuner of claim 1, wherein the set of N SI unit cells are collectively configured to draw the discharging current from or supply the charging current to the capacitor during the fourth time interval based on a thermometer code k indicated by the enable signal EN<N-1:0>.

7. The clock phase tuner of claim 6, wherein the set of N SI unit cells are collectively configured to draw the discharging current from or supply the charging current to the capacitor during the fourth time interval in accordance with (N-k)*I-k*I, wherein I represents substantially a same magnitude of a current generated by each of the set of N SI unit cells, and wherein a negative value of (N-k)*I-k*I indicates the discharging current and a positive value of k*I-(N-k)*I indicates the charging current.

8. The clock phase tuner of claim 1, wherein the set of N SI unit cells are collectively configured to produce substantially no net current to or from the capacitor based on a value of the enable signal EN<N-1:0> during the second time interval.

9. The clock phase tuner of claim 1, wherein the set of N SI unit cells are collectively configured to produce substantially no net current to or from the capacitor based on a value of the enable signal EN<N-1:0> during the fourth time interval.

10. The clock phase tuner of claim 1, wherein the clock generator comprises a transimpedance amplifier (TIA).

11. The clock phase tuner of claim 10, wherein the TIA comprises:
an inverter-based amplifier;
an alternating-current (AC)-coupled capacitor coupled between a common output of the set of N SI unit cells and an input of the inverter-based amplifier; and
a feedback resistor coupled between an output and the input of the inverter-based amplifier.

12. The clock phase tuner of claim 10, further comprising a driver including an input coupled to an output of the TIA, wherein the driver is configured to generate the output clock signal.

13. A clock phase tuner, comprising:
a set of N switched-current (SI) unit cells, wherein each of the set of N SI unit cells comprises:
a first p-channel field effect transistor (PFET) coupled in series with a first current source between an upper voltage rail and a common output of the set of N SI unit cells, wherein the first PFET includes a gate configured to receive a first clock signal, and wherein the first current source is enabled based on a corresponding bit of an enable signal EN<N-1:0>;
a second current source coupled in series with a first n-channel field effect transistor (NFET) between the common output and a lower voltage rail, wherein the first NFET includes a gate configured to receive the first clock signal, and wherein the second current source is enabled based on the corresponding bit of the enable signal EN<N-1:0>;
a second PFET coupled in series with a third current source between the upper voltage rail and the common output of the set of N SI unit cells, wherein the second PFET includes a gate configured to receive a second clock signal, and wherein the third current source is enabled based on a corresponding bit of a complementary enable signal EN_b<N-1:0>; and
a fourth current source coupled in series with a second NFET between the common output and the lower voltage rail, wherein the second NFET includes a gate configured to receive the second clock signal, wherein the fourth current source is enabled based on the corresponding bit of the complementary enable signal EN_b<N-1:0>;
a capacitor coupled between the common output and the lower voltage rail; and
a clock generator including an input coupled to the common output, and an output configured to generate a clock signal.

14. The clock phase tuner of claim 13, further comprising a control circuit configured to adjust the first and third current sources and/or the second and fourth current sources to control a common mode voltage associated with the voltage.

15. A method of generating a clock signal, comprising:
supplying a charging current to a capacitor when a first clock signal and a second clock signal are both at a first logic state to generate a voltage across the capacitor during a first time interval;
supplying a charging current to or drawing a discharging current from the capacitor based on an enable signal when the first clock signal is at the first logic state and the second clock signal is at a second logic state to generate the voltage across the capacitor during a second time interval;
drawing a discharging current from the capacitor when the first clock signal and the second clock signal are both at the second logic state to generate the voltage during a third time interval;
drawing a discharging current from or supplying a charging current to the capacitor based on the enable signal when the first clock signal is at the second logic state and the second clock signal is at the first logic state to generate the voltage across the capacitor during a fourth time interval; and
generating a clock signal based on the voltage.

16. The method of claim 15, wherein supplying the charging current during the first time interval comprises supplying the charging current with a magnitude substantially independent of the enable signal.

17. The method of claim 15, wherein supplying the charging current to or drawing the discharging current from the capacitor during the second time interval comprises supplying the charging current or drawing the discharging current in accordance with k*I-(N-k)*I, wherein k is a thermometer code indicated by the enable signal and N is an integer, wherein I is substantially 1/N times a magnitude of a maximum charging current or a maximum discharging current, and wherein a positive value of k*I-(N-k)*I indicates the charging current and a negative value of k*I-(N-k)*I indicates the discharging current.

18. The method of claim 15, wherein drawing the discharging current from the capacitor during the third time interval comprises drawing the discharging current with a magnitude substantially independent of a value of the enable signal.

19. The method of claim 15, wherein drawing the discharging current from or supplying the charging current to the capacitor during the fourth time interval comprises drawing the discharging current or supplying the charging current in accordance with (N-k)*I-k*I, wherein k is a thermometer code indicated by the enable signal and N is an integer, wherein I is substantially 1/N times a magnitude of a maximum discharging current or a maximum charging current, and wherein a negative value of (N-k)*I-k*I indicates the discharging current and a positive value of (N-k)*I-k*I indicates the charging current.

20. The method of claim 15, further comprising producing substantially no net current to or from the capacitor based on a value of the enable signal during the second time interval or the fourth time interval.
